(19) United States
(12) Patent Application Publication
(10) Pub. No.: US 2026/0190905 A1
(43) Pub. Date: Jul. 2, 2026

(54) SUBSTRATE PROCESSING APPARATUS

(71) Applicant: SEMES CO., LTD., Cheonan-si (KR)

(72) Inventors: Sung Hun EOM, Hwaseong-si (KR); Ki Moon KANG, Yongin-si (KR); Kyu Hwan CHANG, Hwaseong-si (KR)

(73) Assignee: SEMES CO., LTD., Cheonan-si (KR)

(21) Appl. No.: 19/430,700

(22) Filed: Dec. 23, 2025

(30) Foreign Application Priority Data
Dec. 26, 2024 (KR) 10-2024-0197637

(51) Int. Cl. H10P 72/00

(52) U.S. Cl. CPC H10P 72/0414; H10P 72/0402

(57) ABSTRACT

The apparatus features a plurality of treating chambers arranged vertically for processing a substrate. The treatment liquid supply unit manages the liquid flow from a supply source via upstream and downstream lines. the plurality of pump units are (each comprising a pump and filter) installed on the downstream lines and positioned at different heights. These feed the liquid to the chambers. For discharge, a drainage line, including a vertical line that drains downward, is connected to the pump units. This vertical line incorporates a plurality of pressure compensation units to stabilize the pressure within the drainage line.

### CROSS-REFERENCE TO RELATED APPLICATION

This application claims priority to and the benefit of Korean Patent Application No. 10-2024-0197637 filed in the Korean Intellectual Property Office on Dec. 26, 2024, the entire contents of which are incorporated herein by reference.

### TECHNICAL FIELD

The present invention relates to a treatment liquid supply unit and a substrate processing apparatus including the same, and more specifically, to a treatment liquid supply unit that controls negative pressure applied to a pump supplying a treatment liquid, and a substrate processing apparatus that processes a substrate with a treatment liquid supplied by the treatment liquid supply unit.

### BACKGROUND ART

The semiconductor process includes a process of removing or cleaning thin films, foreign substances, and particles formed on a substrate, and this cleaning process is performed in a treating chamber. When the substrate is loaded into the treating chamber, the substrate is placed on a spin head so that a pattern surface of the substrate faces up or down, and a treatment liquid is supplied to the surface of the substrate while rotating the spin head and then the substrate is dried.

In general, a treating chamber has a structure in which a plurality of chambers is stacked. However, due to the stacked structure, a difference in height occurs between each chamber. When the treatment liquid is supplied to all treating chambers using a single pump, the pressure delivered to each chamber is different, resulting in a problem that the substrate treatment uniformity is deteriorated. To solve this problem, it has been proposed to secure substrate treatment uniformity by arranging individual pumps for each layer in which each chamber is installed and supplying the treatment liquid at the same pressure.

However, in order to drain the treatment liquid remaining in a treatment liquid supply path or the treatment liquid remaining in a filter, a drainage line is installed downstream of each pump, which causes a problem in which negative pressure is formed in the pump. In a laminated structure, the drain line includes a vertical pipe having a length in the vertical direction, because when the chemical treatment liquid is drained through the vertical pipe, it is drained under the influence of gravity. When negative pressure is generated in the pump, the pump is required to have higher pressure to supply the treatment liquid, requiring a high-performance pump. In addition, it causes the possibility that bubbles are generated in the supplied treatment liquid due to the negative pressure. In addition, since the length of the vertical pipe is different for each layer, the negative pressure applied to each pump is also different, causing a difference in supply pressure, which hinders the uniformity of substrate processing.

### SUMMARY OF THE INVENTION

The present invention has also been made in an effort to provide a substrate processing apparatus capable of supplying a treatment liquid with the same pressure even if the heights of the chambers are different from each other.

The present invention has also been made in an effort to provide a substrate processing apparatus capable of minimizing negative pressure applied to a pump.

The present invention has also been made in an effort to provide a substrate processing apparatus capable of improving substrate processing uniformity by uniformly applying negative pressure to pumps having different heights.

The objectives of the present disclosure are not limited thereto and other objectives not stated herein may be clearly understood by those skilled in the art from the following description.

An exemplary embodiment of the present disclosure, an apparatus for processing a substrate, the apparatus comprising: a plurality of treating chambers which processes a substrate with a treatment liquid and is arranged in a vertical direction; and a treatment liquid supply unit for supplying a treatment liquid to the plurality of treating chambers, wherein the treatment liquid supply unit includes: a treatment liquid supply source for storing and supplying the treatment liquid; an upstream supply line connected to the treatment liquid supply source; a plurality of downstream supply lines branching from the upstream supply line to be connected to each of the plurality of treating chambers; a pump unit installed on each of the downstream supply lines to feed the treatment liquid from the treatment liquid supply source to the treating chamber; a drainage line which is connected to the pump unit to discharge the treatment liquid, and includes a vertical line that discharges the treatment liquid vertically downward; and a plurality of pressure compensation units installed on the vertical line and compensating for a pressure in the drainage line, the pump unit includes: a pump for pressurizing and feeding the treatment liquid; and a filter for filtering the treatment liquid, and the plurality of pump units may be arranged at different heights.

According to the exemplary embodiment of the present invention, wherein the pump unit may be provided at a height corresponding to each of the plurality of treating chambers.

According to the exemplary embodiment of the present invention, wherein each of the pressure compensation units may be installed below the pump unit corresponding to each of the pressure compensation units.

According to the exemplary embodiment of the present invention, wherein each of the pressure compensation units may be installed higher as a position of the pump unit corresponding to each of the pressure compensation units is higher.

According to the exemplary embodiment of the present invention, wherein each of the pressure compensation units may be installed above the pump unit located below the pump unit corresponding to each of the pressure compensation units.

According to the exemplary embodiment of the present invention, wherein a height difference between each of the pressure compensation units and the corresponding pump unit may be the same.

According to the exemplary embodiment of the present invention, wherein the drainage line includes: a first drainage line connected to the pressure compensation unit upstream of the pressure compensation unit; and a second drainage line connected to the pressure compensation unit downstream of the pressure compensation unit, the pressure compensation unit is a reverse flow line, and the reverse flow line connects the first drainage line and the second drainage line, but may be provided to rise when the treatment liquid flows from the first drainage line to the second drainage line.

According to the exemplary embodiment of the present invention, wherein the drainage line includes: a first drainage line connected to the pressure compensation unit upstream of the pressure compensation unit; and a second drainage line connected to the pressure compensation unit downstream of the pressure compensation unit, the pressure compensation unit includes a body with a space inside, and the first drainage line and the second drainage line may be coupled to the body.

According to the exemplary embodiment of the present invention, wherein the pressure compensation unit further may includes: an open line connected to the body; and a valve installed on the open line.

According to the exemplary embodiment of the present invention, wherein the pump unit further may include a circulation line branching downstream of the filter and joining upstream of the pump.

According to the exemplary embodiment of the present invention, wherein the treatment liquid may be photoresist.

According to the exemplary embodiment of the present invention, wherein the treatment liquid supply unit may include a drain box connected to the plurality of drainage lines to discharge the treatment liquid drained from the drainage line to the outside, the drain box includes: a housing having an inner space and a bottom surface inclined downward from one side to the other; a plurality of inflow lines connecting each of the plurality of drainage lines and the housing; a gas supply unit for supplying gas to the inner space; a dissolution liquid supply unit for supplying a dissolution liquid to the inner space; and a discharge line for discharging the treatment liquid, the gas, and the dissolution liquid from the inner space.

An exemplary embodiment of the present disclosure, an apparatus for processing a substrate, the apparatus comprising: a plurality of treating chambers which processes a substrate with a treatment liquid and is arranged in a vertical direction; and a treatment liquid supply unit for supplying a treatment liquid to the plurality of treating chambers, wherein the treatment liquid supply unit includes: a treatment liquid supply source for storing and supplying the treatment liquid; an upstream supply line connected to the treatment liquid supply source; a plurality of downstream supply lines branching from the upstream supply line to be connected to the plurality of treating chambers, respectively; a filter installed on each of the plurality of downstream supply lines to filter the treatment liquid; a drainage line that is connected to the filter to discharge the treatment liquid, and includes a vertical line discharging the treatment liquid vertically downward; and a plurality of pressure compensation units installed on the vertical line and compensating for a pressure in the drainage line, and the filters may be arranged at different heights.

According to the exemplary embodiment of the present invention, wherein the pressure compensation unit may be disposed below the filter corresponding to each of the pressure compensation units.

According to the exemplary embodiment of the present invention, wherein a height difference between each of the pressure compensation units and the filter corresponding to each of the pressure compensation units may be the same.

According to the exemplary embodiment of the present invention, wherein the drainage line includes: a first drainage line connected to the pressure compensation unit upstream of the pressure compensation unit; and a second drainage line connected to the pressure compensation unit downstream of the pressure compensation unit, the pressure compensation unit is a reverse flow line, and the reverse flow line connects the first drainage line and the second drainage line, and may be provided to rise when the treatment liquid flows from the first drainage line to the second drainage line.

According to the exemplary embodiment of the present invention, wherein the drainage line includes: a first drainage line connected to the pressure compensation unit upstream of the pressure compensation unit; and a second drainage line connected to the pressure compensation unit downstream of the pressure compensation unit, the pressure compensation unit includes: a body having a space therein; an open line connected to the body; and a valve installed in the open line, and the first drainage line and the second drainage line may be coupled to the body.

An exemplary embodiment of the present disclosure, an apparatus for processing a substrate, the apparatus comprising: a plurality of treating chambers which processes a substrate with a treatment liquid and is arranged in a vertical direction; and a treatment liquid supply unit for supplying a treatment liquid to the plurality of treating chambers, wherein the treatment liquid supply unit includes: a treatment liquid supply source for storing and supplying the treatment liquid; an upstream supply line connected to the treatment liquid supply source; a plurality of downstream supply lines branching from the upstream supply line to be connected to the plurality of treating chambers, respectively; a pump unit installed on each of the downstream supply lines to feed the treatment liquid from the treatment liquid supply source to the treating chamber; a drainage line which is connected to the pump unit to discharge the treatment liquid, and includes a vertical line discharging the treatment liquid vertically downward; and a plurality of pressure compensation units installed on the vertical line and compensating for a pressure in the drainage line, and a drain box connected to the plurality of drainage lines to discharge the treatment liquid drained from the drainage line to the outside, the treatment liquid is photoresist, the pump unit includes: a pump for pressurizing and feeding the treatment liquid; and a filter for filtering the treatment liquid, and the pump unit is provided at a height corresponding to each of the plurality of treating chambers, and each of the pressure compensation units is provided to have the same height difference as the corresponding pump unit, each of the pressure compensation units being disposed below the corresponding pump unit and being disposed above the pump unit may disposed below the corresponding pump unit.

According to the exemplary embodiment of the present invention, wherein the drainage line includes: a first drainage line connected to the pressure compensation unit upstream of the pressure compensation unit; and a second drainage line connected to the pressure compensation unit downstream of the pressure compensation unit, the pressure compensation unit is a reverse flow line, and the reverse flow line connects the first drainage line and the second drainage line, and may be provided to rise when the treatment liquid flows from the first drainage line to the second drainage line.

According to the exemplary embodiment of the present invention, wherein the drainage line includes: a first drainage line connected to the pressure compensation unit upstream of the pressure compensation unit; and a second drainage line connected to the pressure compensation unit downstream of the pressure compensation unit, the pressure compensation unit includes: a body having a space therein; an open line connected to the body; and a valve installed in the open line, and the first drainage line and the second drainage line may be coupled to the body.

According to the exemplary embodiment of the present invention, it is possible to supply a treatment liquid with the same pressure even if the heights of the chambers are different from each other.

Further, according to the exemplary embodiment of the present invention, it is possible to minimize negative pressure applied to a pump.

Further, according to the exemplary embodiment of the present invention, it is possible to improve substrate processing uniformity by uniformly applying negative pressure to pumps having different heights.

Effects of the present disclosure are not limited to those described above and effects not stated above will be clearly understood to those skilled in the art from the specification and the accompanying drawings.

### BRIEF DESCRIPTION OF THE DRAWINGS

The various features and advantages of the non-limiting exemplary embodiment of the present specification may become more apparent by reviewing the detailed description together with the accompanying drawings. The accompanying drawings are provided for illustrative purposes only and should not be construed as limiting the scope of claims. The accompanying drawings are not considered to be drawn to scale unless explicitly stated. For clarity, the various dimensions of the drawings may have been exaggerated.

FIG. 1 is a perspective view schematically illustrating a substrate processing apparatus according to an exemplary embodiment of the present invention.

FIG. 2 is a side view of the substrate processing apparatus of FIG. 1.

FIG. 3 is a front view schematically illustrating the liquid treating chamber of FIG. 2

FIG. 4 is a diagram illustrating the treatment liquid supply unit 1000 according to the exemplary embodiment of the present invention..

FIG. 5 is a diagram schematically illustrating an exemplary embodiment of the pressure compensation unit of FIG. 4.

FIG. 6 is a diagram schematically illustrating another exemplary embodiment of the pressure compensation unit of FIG. 4

FIG. 7 is a diagram schematically illustrating an exemplary embodiment of the drain box

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, a wafer is described as an example as a target to be treated. However, the technical spirit of the present invention may be applied to apparatuses used for treating other types of substrates, other than wafers, as targets to be treated.

Hereinafter, an exemplary embodiment of the present invention will be described with reference to the accompanying drawings.

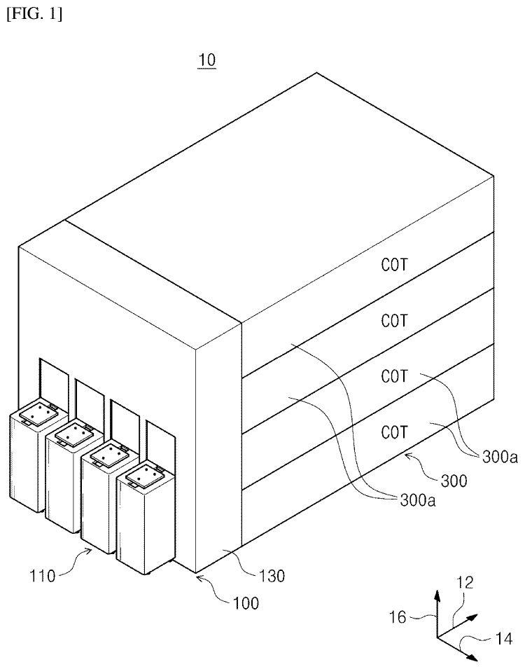

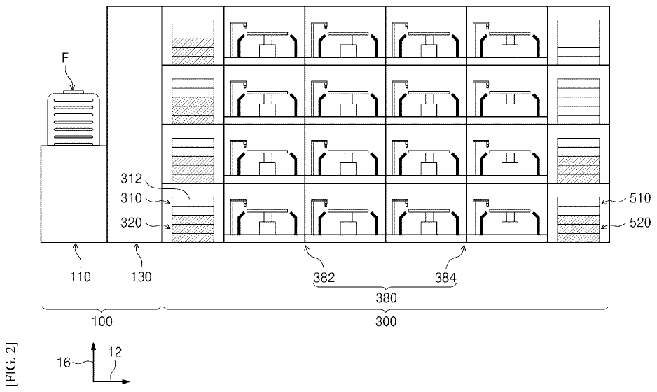

FIG. 1 is a perspective view schematically illustrating a substrate processing apparatus according to an exemplary embodiment of the present invention, and FIG. 2 is a side view of the substrate processing apparatus of FIG. 1.

Referring to FIGS. 1 to 2, a substrate processing apparatus 10 includes an index module 100 and a treating module 300. According to an example, the index module 100 and the treating module 300 are sequentially arranged in a line. Hereinafter, a direction in which the index module 100 and the treating module 300 are disposed is referred to as a first direction 12, and when viewed from above, a direction perpendicular to the first direction 12 is referred to as a second direction 14, and a direction perpendicular to both the first direction 12 and the second direction 14 is referred to as a third direction 16.

The index module 100 is provided to transfer the substrate W between a container F in which the substrate W is accommodated and the treating module 300. A longitudinal direction of the index module 100 is provided in the second direction 14. The index module 100 includes a load port 110 and an index frame 130. The containers F in which the substrates W are accommodated are placed on the load ports 110. Based on the index frame 130, the load port 110 is located at a side opposite to the treating module 300. A plurality of load ports 110 may be provided, and the plurality of load ports 110 may be disposed in the second direction 14.

For example, as the container F, an airtight container F, such as a Front Open Unified Pod (FOUP), may be used. The container F may be placed on the load port 110 by a transfer means (not illustrated), such as an overhead transfer, an overhead conveyor, or an automatic guided vehicle, or an operator.

An index robot (not illustrated) is provided to the inside of the index frame 130. A guide rail (not illustrated) is provided to the inside of the index frame 130. A longitudinal direction of the guide rail is provided in the second direction 14. The index robot is mounted on the guide rail to be movable along the guide rail. The index robot includes a hand on which the substrate W is placed. The hand may be provided to be movable forward and backward, linearly movable in the third direction, and rotatable in the third direction 16.

The treating module 300 may perform a coating process on the substrate W. The treating module 300 may include a coating block 300a for performing a coating process.

The coating block 300a performs a coating process on the substrate W before an exposure process is performed. A plurality of coating blocks 300a is provided. A plurality of coating blocks 300a may be provided to be stacked on each other. According to an example, four coating blocks 300a may be provided.

A plurality of coating blocks 300a may be provided in the same structure. The films applied to the substrate W in each of the plurality of coating blocks 300a may be the same type of film. Optionally, depending on the coating block 300a, the films applied to the substrate W may be different types of films. The film coated on the substrate W includes a photo-resist film. The film coated on the substrate W may further include an anti-reflection film. Optionally, the film coated on the substrate W may further include a protective film.

the coating block 300a may include a buffer unit 310, a cooling unit 320, a liquid treating chamber 380, and a treatment liquid supply unit 1000.

The buffer unit 310 and the cooling unit 320 are disposed adjacent to the index block 100. The cooling unit 320 and the buffer unit 310 may be provided to be stacked in a vertical direction.

The buffer unit 310 includes one or a plurality of buffers 312. When a plurality of buffers 312 is provided, the plurality of buffers 312 may be disposed to be stacked therebetween. The buffer 312 provides a space in which the substrate W stays when the substrate W is transferred between the index module 100 and the treating module 300.

The cooling unit 320 cools the substrate W. The cooling unit 320 includes one or a plurality of cooling plates. When a plurality of cooling plates is provided, a plurality of cooling plates may be disposed to be stacked on each other. According to an example, the cooling unit 320 may be disposed below the buffer unit 310. A flow path through which cooling water flows may be formed in the cooling plate. The substrate W on which the hydrophobization treatment has been completed may be cooled in the cooling plate.

The liquid treating chamber 380 performs a liquid film forming process of forming a liquid film composed of a treatment liquid on the substrate W. According to an example, the liquid film forming process includes a resist film forming process. The liquid film forming process may include an antireflection film forming process. Optionally, the liquid film forming process may further include a protective film forming process. A plurality of liquid treating chambers 380 is provided. The liquid treating chambers 380 may be located on the side opposite to the heat treating chamber 360. For example, all liquid treating chambers 380 may be located on the other side of the transfer chamber 350. The liquid treating chambers 380 are arranged side by side along the first direction 12. Optionally, some of the liquid treating chambers 360 may be stacked along the third direction 16.

According to an example, the liquid treating chambers 380 include a front end liquid treating chamber 382 and a rear end liquid treating chamber 384. The front end liquid treating chamber 382 is disposed relatively adjacent to the index module 100, and the rear end liquid treating chamber 384 is disposed more adjacent to the interface module 500.

The front end liquid treating chamber 382 coats the substrate W with a first liquid, and the rear end liquid treating chamber 384 coats the substrate W with a second liquid. The first treatment liquid and the second treatment liquid may be different types of liquids. According to an example, the first treatment liquid may be a treatment liquid for forming the antireflection film, and the second treatment liquid may be a treatment liquid for forming the photoresist film. The photoresist film may be formed on the substrate W on which the antireflection film is coated. Optionally, the first treatment liquid may be a treatment liquid for forming the photoresist film, and the second treatment liquid may be a treatment liquid for forming the antireflection film. In this case, the antireflection film may be formed on the substrate W on which the photoresist film is formed. Optionally, the first treatment liquid and the second treatment liquid may be the same type of treatment liquid, and all of these may be treatment liquids for forming a photoresist film.

The treatment liquid supply unit 1000 is provided to supply the treatment liquid to the liquid treating chamber 380. More details regarding the treatment liquid supply unit 1000 will be discussed later.

Furthermore, the coating block 300a includes a robot for transferring the substrate W between units. A plurality of robots may be provided, and a plurality of hands for holding the substrate W may also be provided.

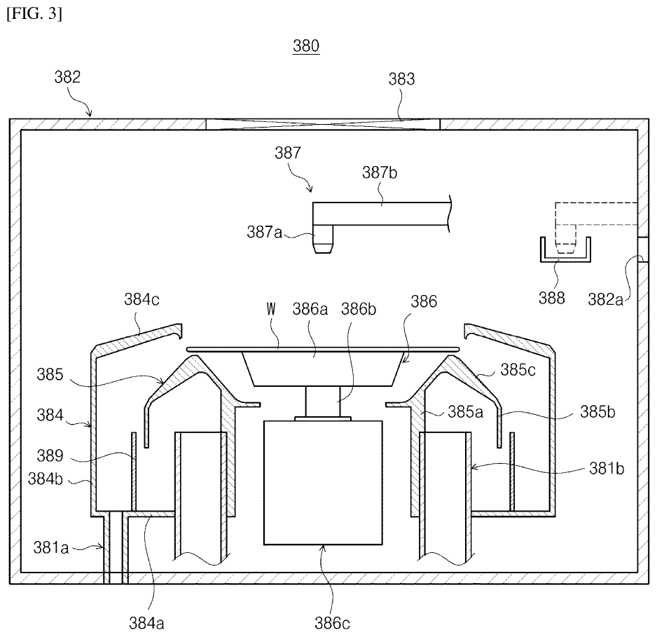

FIG. 3 is a front view schematically illustrating the liquid treating chamber of FIG. 2. Referring to FIG. 3, the liquid treating chamber 380 includes a housing 382, an outer cup 384, a support unit 386, and a nozzle unit 387.

The housing 382 is provided in a rectangular cylindrical shape having an inner space. An opening 382a is formed in one side of the housing 382. The opening 382a functions as a passage through which the substrate W enters and exits. A door (not illustrated) is installed in the opening 382a, and the door opens and closes the opening.

A fan filter unit 383 for supplying downward airflow to the inner space is disposed on the upper wall of the housing 382. The fan filter unit 383 has a fan for introducing outside air into the inner space and a filter for filtering the outside air.

The outer cup 384 is provided in the inner space of the housing 382. The outer cup 384 has a treatment space with an open top. The outer cup 384 has a bottom wall 384a, a sidewall 384b, and an upper wall 384c. The inside of the outer cup 384 is provided as the aforementioned inner space. The inner space H includes an upper treatment space and a lower exhaust space.

The bottom wall 384a is provided in a circular shape and has an opening in the center thereof. The sidewall 384b extends upward from the outer end of the bottom wall 384a. The sidewall 384b is provided in a ring shape and is provided perpendicular to the bottom wall 384a. For example, the sidewall 384b extends to the same height as the upper surface of the support plate 386a or extends to a height slightly lower than the upper surface of the support plate 386a. The upper wall 384c has a ring shape and an opening in the center thereof. The upper wall 384c is provided to be inclined upward from the upper end of the sidewall 384b toward the central axis of the outer cup 384.

The guide cup 385 is located inside the outer cup 384. The guide cup 385 has an inner wall 385a, an outer wall 385b, and an upper wall 385c. The inner wall 385a has a through hole penetrating in the vertical direction. The inner wall 385a is disposed to surround a driver 386c. The inner wall 385a minimizes the exposure of the driver 386c to the airflow 84 in the treatment space. A rotary shaft 386b or/and the driver 386c of the support unit 386 extend in the vertical direction through the through hole. The outer wall 385b is disposed to be spaced apart from the inner wall 385a and to surround the inner wall 385a. The outer wall 385b is positioned to be spaced apart from the sidewall 384b of the outer cup 384. The inner wall 385a is disposed to be spaced apart upward from the bottom wall 384a of the outer cup 384. The upper wall 385c connects the upper end of the outer wall 385b and the upper end of the inner wall 385a. The upper wall 385c has a ring shape and is disposed to surround the support plate 386a. According to an example, the upper wall 385c has a shape convex upward.

In the treatment space, a space below the support plate 386a may be provided as an exhaust space. According to an example, the exhaust space may be defined by the guide cup 385. A space surrounded by or below the outer wall 385b, the upper wall 385c, and the inner wall 385a of the guide cup 385 may be provided as an exhaust space.

The outer cup 384 may also be provided with a gas-treatment liquid separator 389. The gas-treatment liquid separator 389 may extend upward from the bottom wall 384a of the outer cup 384. The gas-treatment liquid separator 389 may be provided in a ring shape. When viewed from above, the gas-treatment liquid separator 389 may be positioned between the sidewall 384b of the outer cup 384 and the outer wall 385b of the guide cup 385. The upper end of the gas-treatment liquid separator 389 may be positioned lower than the lower end of the outer wall 385b of the guide cup 385.

A discharge pipe 381a and an exhaust pipe 381b for discharging the treatment liquid are connected to the bottom wall 384a of the outer cup 384. The discharge pipe 381a may be connected to the outer cup 384 from the outside of the gas-treatment liquid separator 389. The exhaust pipe 381b may be connected to the outer cup 384 from the inside of the gas-treatment liquid separator 389.

The support unit 386 supports the substrate W in the treatment space of the outer cup 384. The support unit 386 includes the support plate 386a, the rotary shaft 386b, and the driver 386c. The support plate 386a has a circular upper surface. The support plate 386a has a smaller diameter than the substrate W. The support plate 386a is provided to support the substrate W by vacuum pressure. The rotary shaft 386b is coupled to the center of the bottom surface of the support plate 386a, and the rotary shaft 386b is provided with the driver 386c that provides the rotary shaft 386b with rotating force. The driver 386c may be a motor. Also, a lifting driver (not illustrated) for adjusting a relative height of the support plate 386a and the outer cup 384 may be provided.

The nozzle unit 387 supplies a treatment liquid onto the substrate W. When the liquid treating chamber 380 is provided to the coating block 300a, the treatment liquid may be a treatment liquid for forming a photoresist film, an antireflection film, or a protective film. When the liquid treating chamber 380 is provided to the developing block 300b, the treatment liquid may be a developer. The nozzle unit 387 includes a nozzle 387a, a nozzle support 387b, and a treatment liquid supply source (not illustrated). The nozzle 387a discharges the treatment liquid to the substrate W. The nozzle 387a is supported by the nozzle support 387b. The nozzle support 387b moves the nozzle 387a between a process position and a standby position. In the process position, the nozzle 387a supplies the treatment liquid to the substrate W placed on the support plate 386a, and the nozzle 387a, which has completed supplying the treatment liquid, waits in the standby position. In the standby position, the nozzle 387a stands by at the home port 388, and the home port 388 is located outside the outer cup 384 within the housing 382.

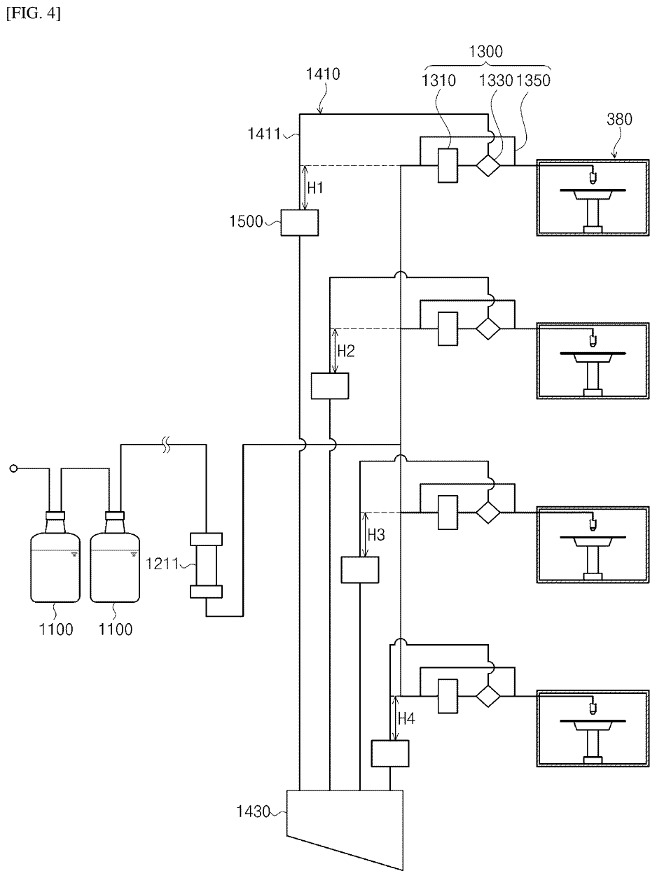

FIG. 4 is a diagram illustrating the treatment liquid supply unit 1000 according to the exemplary embodiment of the present invention. Referring to FIG. 4, the treatment liquid supply unit 1000 may supply a treatment liquid to a plurality of liquid treating chambers 380. Here, the plurality of liquid treating chambers 380 may be provided with different heights from each other. Also, the treatment liquid supply unit 1000 may include a treatment liquid supply source 1100, a treatment liquid supply line 1200, and a pump unit 1300.

The treatment liquid supply unit 1000 may supply the treatment liquid to the plurality of liquid treating chambers 380. Here, the plurality of liquid treating chambers 380 may be provided with different heights from each other. Further, the treatment liquid supply unit 1000 may include a treatment liquid supply source 1100, a treatment liquid supply line 1200, a pump unit 1300, a drainage unit 1400, and a pressure compensation unit 1500.

The treatment liquid supply source 1100 may store the treatment liquid. Also, the treatment liquid supply source 1100 may supply the treatment liquid to the treatment liquid supply line 1200 by a treatment liquid supply means, which is not illustrated. A plurality of treatment liquid supply sources 1100 may be provided. A plurality of treatment liquid supply sources 1100 may be provided to be connected to each other. The treatment liquid supply source 1100 may be connected to the liquid treating chamber 380 by the treatment liquid supply line 1200.

The treatment liquid supply line 1200 may include an upstream supply line 1210 and a plurality of downstream supply lines 1220. One end of the upstream supply line 1210 is connected to the treatment liquid supply source 1100, and the other end thereof is connected to a plurality of downstream supply lines 1220. One end of the plurality of downstream supply lines 1220 is connected to the upstream supply line 1210, and the other end thereof is connected to the liquid treating chamber 380. Optionally, when the plurality of liquid treating chambers 380 is provided at the same height, a second downstream supply line branching again from the downstream supply line 1220 may be further included. Also, a trap tank 1211 may be provided in the upstream supply line 1210. The trap tank 1211 is provided so that the treatment liquid supplied from the treatment liquid supply source 1100 is temporarily stored.

The pump unit 1300 may be installed in the treatment liquid supply line 1200. The pump unit 1300 may be provided in a number corresponding to the number of liquid treating chambers 380, and the pump unit 1300 may be installed in each downstream supply line 1220. Each pump unit 1300 may be installed at the same height as each liquid treating chamber 380. The pump unit 1300 may be provided to pressurize and feed the treatment liquid. The pump unit 1300 may include a pump 1310, a filter 1330, and a circulation line 1350.

The pump 1310 supplies the treatment liquid from the treatment liquid supply source 1100 to the liquid treating chamber 380. The pump 1310 pressurizes and feed the treatment liquid. According to an example, the pump 1310 may be a diaphragm pump.

The filter 1330 may filter the treatment liquid flowing in the treatment liquid supply line 1200. The filter 1330 may improve the cleanliness of the treatment liquid by removing particles, air bubbles, and the like in the treatment liquid. The filter 1330 may be installed downstream from the pump 1310. The filter 1330 may be installed closer to the liquid treating chamber 380 than the pump 1310.

The circulation line 1350 is provided so that the treatment liquid is circulated in the pump unit 1300. The circulation line 1350 may be provided to branch downstream of the filter 1330 and join upstream of the pump 1310. By circulating the treatment liquid through the circulation line 1350, it is possible to prevent the treatment liquid from stagnating.

Optionally, a pressure sensor 1370 may be provided at a downstream side of the pump 1310 and/or a downstream side of the filter 1330. The pressure sensor 1370 may measure pressure in the downstream supply line 1222. It may be determined whether negative pressure is formed through the pressure sensor 1370. Also, a plurality of valves 1390 may be provided. A plurality of valves 1390 may control whether a treatment liquid is supplied to the nozzle 387a and whether the treatment liquid is circulated.

The drainage unit 1400 is provided to drain the treatment liquid remaining in the downstream supply line 1220, the pump 1310, the filter 1330, and the like. The drainage may be performed for various purposes. For example, the purpose may be maintaining process quality, preventing reuse and waste of treatment liquid, protecting filters and pumps. The drainage unit 1400 may include a drainage line 1410 and a drain box 1430.

The drainage line 1410 may be installed on the filter 1330. The drainage line 1410 provides a path to drain the treatment liquid remaining in the downstream supply line 1220, the pump 1310, the filter 1330, and the like. One end of the drainage line 1410 may be connected to the filter 1330, and the other end thereof may be connected to the drain box 1430. Accordingly, foreign substances, such as particles, filtered by the filter 1330 may be discharged to the drain box 1430. The drainage line 1410 may include a vertical line 1411. The vertical line 1411 is provided so that the drained treatment liquid flows in the vertical direction. The vertical line 1411 may be provided to be longer as the pump unit 1300 is positioned higher.

The vertical line 1411 may include a first vertical line 1411a and a second vertical line 1411b. The first vertical line 1411a is located upstream from the second vertical line 1411b. A pressure compensation unit 1500 to be described later may be provided between the first vertical line 1411a and the second vertical line 1411b.

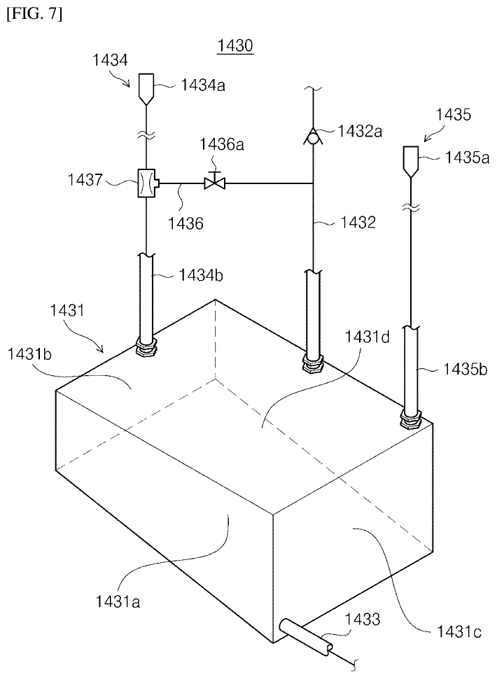

FIG. 7 is a diagram schematically illustrating an exemplary embodiment of the drain box. Referring to FIG. 7, the drain box 1430 may include a housing 1431, an inlet pipe 1432, a discharge pipe 1433, a gas supply unit 1434, a dissolution liquid supply unit 1435, and a recovery pipe 1436.

The housing 1431 has an inner space. A treatment liquid drained through the inlet pipe 1432 may temporarily remain in the inner space of the housing 1431. The inlet pipe 1432, the discharge pipe 1433, the gas supply pipe 1434b, and the dissolution liquid supply pipe 1435b, which will be described later, may be connected to the housing 1431.

The bottom surface 1431a of the housing 1431 may be provided to be inclined downward from one side to the other side. For example, the bottom surface 1431a may be provided to be inclined downward from a first side surface 1431b of the hole to which the gas supply pipe 1434b is connected to a second side surface 1431c of the hole to which the discharge pipe 1433 is connected. Accordingly, the treatment liquid in the housing 1431 may be efficiently discharged to the outside through the discharge pipe 1433.

The inlet pipe 1432 is connected to the drainage line 1410, and allows the treatment liquid drained from the filter 1330 to be introduced into the housing 1431. The inflow pipe 1432 may be provided with a check valve 1432a for preventing reverse flow of the treatment liquid.

The gas supply unit 1434 supplies high-pressure gas to the inner space of the housing 1431, and discharges the treatment liquid remaining in the inner space to the discharge pipe 1433. The gas supply unit 1434 includes a gas supply source 1434a and a gas supply pipe 1434b. The gas supply source 341 stores high-pressure gas. According to an example, the gas may be inert gas. For example, the gas may be nitrogen gas (N₂). The gas supply pipe 1434 is connected to the housing 1431 and supplies the gas stored in the gas supply source 1434a to the inner space. According to an example, the gas supply pipe 1434b may be connected to the edge side of an upper surface 1431a of the drain box 1431. For example, the gas supply pipe 1434b may be connected to the first side surface 1431b side from an upper surface 1431d of the housing 1431. The gas supply pipe 1434b may be mounted with an opening/closing valve (not illustrated) for opening and closing the internal flow path thereof.

The dissolution liquid supply unit 1435 supplies a dissolution liquid to the inner space of the housing 1431. The dissolution liquid supply unit 1435 includes a dissolution liquid supply source 1435a and a dissolution liquid supply pipe 1435b. The dissolution liquid supply source 1435a stores the dissolution liquid. The dissolution liquid may be a liquid that dissolves a photoresist to prevent solidification. According to an example, the dissolution liquid may be a thinner. The dissolution liquid supply pipe 1435b is connected to the housing 1431 and supplies the dissolution liquid stored in the dissolution liquid supply source 1435a to the inner space. The dissolution liquid supplied to the inner space is uniformly mixed with the treatment liquid by the gas supplied by the gas supply unit 1434 and dissolves the treatment liquid. The dissolution liquid supply pipe 1435b may be mounted with an opening/closing valve (not illustrated) for opening and closing the internal flow path thereof.

The recovery pipe 1436 is branched from the inlet pipe 1432 to recover a treatment liquid or fume flowing back to the inlet pipe 1432 to the housing 1431. According to an example, the recovery pipe 1436 may be branched from the inlet pipe 1432 at the downstream side relative to the check valve 1432a. The recovery pipe 1436 is mounted with an opening/closing valve 361 for opening and closing the internal flow path thereof.

An ejector 1437 having an inlet port, an outlet port, and a suction port may be installed in the gas supply pipe 1434b, and the recovery pipe 1436 may be connected to the suction port of the ejector 1437. A gas supply pipe 1434b connected to the gas supply source 1434a in the gas supply pipe 1434b may be connected to the inlet port of the ejector 1437, and a gas supply pipe 1434b connected to the housing 1431 in the gas supply pipe 1434b may be connected to the outlet port. The high-pressure gas supplied by the gas supply source 1434a flows inside the ejector 1437 through the gas supply pipe 1434b to form a negative pressure in the ejector 1437. The treatment liquid or fume flowing back to the inlet pipe 1432 sequentially flows through the recovery pipe 1436 and the gas supply pipe 1434b by the negative pressure formed inside the ejector 1437, and is recovered to the housing 1431.

Referring back to FIG. 4, the pressure compensation unit 1500 may be installed on the drainage line 1410. According to an example, the pressure compensation unit 1500 may be installed on the vertical line 1411. The pressure compensation unit 1500 may be installed between the first vertical line 1411a and the second vertical line 1411b. When the treatment liquid is discharged vertically downward through the vertical line 1411, force that is pulled downward by gravity is generated. In addition, air in the drainage line 1410 may be discharged together with the discharged treatment liquid. Accordingly, the pressure on the pump 1310 decreases as the treatment liquid is discharged. In particular, as the height of the drainage line 1410 is larger, the pressure loss due to gravity is larger, so that the possibility of forming negative pressure in a path through which the treatment liquid is drained is increased. Specifically, negative pressure may be formed in the downstream supply line 1220, the pump 1310 installed in the downstream supply line 1220, the filter 1330, and the drainage line 1410. Hereinafter, this is also referred to as negative pressure being formed on the pump 1310. When negative pressure is formed on the pump 1310, there is a problem that the pump 1310 needs to apply a stronger pressure to the treatment liquid to supply the treatment liquid. The pressure compensation unit 1500 may minimize the negative pressure.

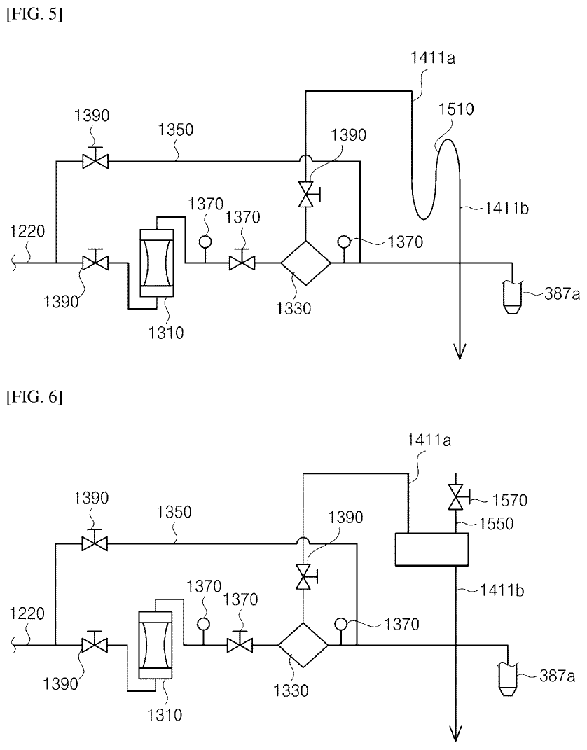

FIG. 5 is a diagram schematically illustrating an exemplary embodiment of the pressure compensation unit of FIG. 4. Referring to FIG. 5, the pressure compensation unit 1500 may be provided to a reverse flow line 1510. The reverse flow line 1510 connects the first drainage line 1411a and the second drainage line 1411b to each other, and is provided to rise when the treatment liquid flows from the first drainage line 1411a to the second drainage line 1411b. Accordingly, the treatment liquid discharged in the process of discharging the treatment liquid through the reverse flow line 1510 flows in the opposite direction to the gravity, thereby reducing the speed of the treatment liquid. This may reduce the generation of negative pressure due to the rapid change in flow velocity. In addition, the pressure distribution in the drainage line 1410 may be made uniform by dispersing the kinetic energy of the treatment liquid.

FIG. 6 is a diagram schematically illustrating another exemplary embodiment of the pressure compensation unit of FIG. 4. Referring to FIG. 6, the pressure compensation unit 1500 includes a body 1530. The body 1530 may be provided to have a space therein. A discharged treatment liquid may remain in the inner space of the body 1530. The first drainage line 1411a may be connected to an upper portion of the body 1530, and the second drainage line 1411b may be connected to a lower portion of the body 1530. When viewed from above, the first drainage line 1411a and the second drainage line 1411b may be provided so as not to overlap each other. By reducing a flow rate of the treatment liquid discharged through such a configuration, it is possible to reduce the negative pressure formed on the pump 1310.

Also, the pressure compensation unit 1500 may include an open line 1550 and a valve 1570. The open line 1550 provides a path through which the atmosphere is introduced. The valve 1570 is provided to open and close the open line 1550. The valve 1570 may be provided as a Normally Opened valve (NO valve).

According to the embodiment of the present invention, the pressure compensation unit 1500 may reduce the energy consumption and operating burden of the pump 1310 by minimizing the negative pressure formed on the pump 1310 side, prevent overload conditions inside the pump due to high pressure, and improve system stability to reduce the possibility of failure.

The pressure compensation unit 1500 may be installed below the pump units 1300-1, 1300-2, 1300-3, and 1300-4 corresponding to the pressure compensation units 1500-1, 1500-2, 1300-3, and 1500-4. Also, the pressure compensation unit 1500 may be installed higher as the positions of the pump unit 1300-1, 1300-2, 1300-3, and 1300-4 corresponding to the pressure compensation units 1500-1, 1500-2, 1500-3, and 1500-4 are higher. Also, the height differences H1, H2, H3, and H4 between the pressure compensation units 1500-1, 1500-2, 1500-3, and 1500-4 and the corresponding respective pressure compensation units 1500-1, 1300-4, 1300-2, 1300-3, and 1300-4, may all be the same. Accordingly, even if the negative pressure is formed on the pump 1310 side, the same negative pressure may be formed. When the same negative pressure is formed, the treatment liquid may be discharged from the nozzle 387a at the same discharge pressure. In this way, substrate treatment uniformity in each liquid treating chamber 380 may be achieved.

In the above example, the present invention has been described based on the case where the pressure compensation unit 1500 includes the open line 1550 and the valve 1570 as an example. However, the present invention is not limited thereto, and the open line 1550 and the valve 1570 may not be provided, and a hole communicating the inside and the outside may be provided on the upper surface of the body 1530.

Furthermore, in the above example, the present invention has been described based on the case where the pump 1310 and the filter 1330 are provided at a height corresponding to the liquid treating chamber 380 as an example. However, the present invention is not limited thereto, and only the filter 1330 is provided at a height corresponding to the liquid treating chamber 380, and the pump 1310 may be provided at a lower portion of the substrate processing apparatus. In this case, the negative pressure is formed on the filter 1330 side instead of the pump side, and the pressure compensation unit 1500 may minimize the negative pressure on the filter 1330.

Further, in the above example, the present invention has been described based on the case where the substrate processing apparatus 10 includes only the index module 100 and the treating module 300 as an example. However, the present invention is not limited thereto, and an interface module may be provided at a rear end of the treating module 300. The interface module serves to connect the treating module 300 to an external device (for example, an exposure apparatus). To this end, the interface module may include a buffer in which the substrate W is temporarily placed, a robot for transferring the substrate W, and the like.

It should be understood that exemplary embodiments are disclosed herein and other modifications may be possible. Individual elements or features of a particular exemplary embodiment are not generally limited to the particular exemplary embodiment, but are interchangeable and may be used in selected exemplary embodiments, where applicable, even when not specifically illustrated or described. The modifications are not to be considered as departing from the spirit and scope of the present disclosure, and all such modifications that would be obvious to one of ordinary skill in the art are intended to be included within the scope of the accompanying claims.

What is claimed is:

1. An apparatus for processing a substrate, the apparatus comprising:
a plurality of treating chambers which processes a substrate with a treatment liquid and is arranged in a vertical direction; and
a treatment liquid supply unit for supplying a treatment liquid to the plurality of treating chambers,
wherein the treatment liquid supply unit includes:
a treatment liquid supply source for storing and supplying the treatment liquid;
an upstream supply line connected to the treatment liquid supply source;
a plurality of downstream supply lines branching from the upstream supply line to be connected to each of the plurality of treating chambers;
a pump unit installed on each of the downstream supply lines to feed the treatment liquid from the treatment liquid supply source to the treating chamber;
a drainage line which is connected to the pump unit to discharge the treatment liquid, and includes a vertical line that discharges the treatment liquid vertically downward; and
a plurality of pressure compensation units installed on the vertical line and compensating for a pressure in the drainage line,
the pump unit includes:
a pump for pressurizing and feeding the treatment liquid; and
a filter for filtering the treatment liquid, and
the plurality of pump units is arranged at different heights.

2. The apparatus of claim 1, wherein the pump unit is provided at a height corresponding to each of the plurality of treating chambers.

3. The apparatus of claim 2, wherein each of the pressure compensation units is installed below the pump unit corresponding to each of the pressure compensation units.

4. The apparatus of claim 3, wherein each of the pressure compensation units is installed higher as a position of the pump unit corresponding to each of the pressure compensation units is higher.

5. The apparatus of claim 4, wherein each of the pressure compensation units is installed above the pump unit located below the pump unit corresponding to each of the pressure compensation units.

6. The apparatus of claim 5, wherein a height difference between each of the pressure compensation units and the corresponding pump unit is the same.

7. The apparatus of claim 1, wherein the drainage line includes:
a first drainage line connected to the pressure compensation unit upstream of the pressure compensation unit; and
a second drainage line connected to the pressure compensation unit downstream of the pressure compensation unit,
the pressure compensation unit is a reverse flow line, and
the reverse flow line connects the first drainage line and the second drainage line, but is provided to rise when the treatment liquid flows from the first drainage line to the second drainage line.

8. The apparatus of claim 1, wherein the drainage line includes:
a first drainage line connected to the pressure compensation unit upstream of the pressure compensation unit; and
a second drainage line connected to the pressure compensation unit downstream of the pressure compensation unit,
the pressure compensation unit includes a body with a space inside, and
the first drainage line and the second drainage line are coupled to the body.

9. The apparatus of claim 8, wherein the pressure compensation unit further includes:
an open line connected to the body; and
a valve installed on the open line.

10. The apparatus of claim 1, wherein the pump unit further includes a circulation line branching downstream of the filter and joining upstream of the pump.

11. The apparatus of claim 1, wherein the treatment liquid is photoresist.

12. The apparatus of claim 1, wherein the treatment liquid supply unit includes a drain box connected to the plurality of drainage lines to discharge the treatment liquid drained from the drainage line to the outside,
the drain box includes:
a housing having an inner space and a bottom surface inclined downward from one side to the other;
a plurality of inflow lines connecting each of the plurality of drainage lines and the housing;
a gas supply unit for supplying gas to the inner space;
a dissolution liquid supply unit for supplying a dissolution liquid to the inner space; and
a discharge line for discharging the treatment liquid, the gas, and the dissolution liquid from the inner space.

13. An apparatus for processing a substrate, the apparatus comprising:
a plurality of treating chambers which processes a substrate with a treatment liquid and is arranged in a vertical direction; and
a treatment liquid supply unit for supplying a treatment liquid to the plurality of treating chambers,
wherein the treatment liquid supply unit includes:
a treatment liquid supply source for storing and supplying the treatment liquid;
an upstream supply line connected to the treatment liquid supply source;
a plurality of downstream supply lines branching from the upstream supply line to be connected to the plurality of treating chambers, respectively;
a filter installed on each of the plurality of downstream supply lines to filter the treatment liquid;
a drainage line that is connected to the filter to discharge the treatment liquid, and includes a vertical line discharging the treatment liquid vertically downward; and
a plurality of pressure compensation units installed on the vertical line and compensating for a pressure in the drainage line, and
the filters are arranged at different heights.

14. The apparatus of claim 13, wherein the pressure compensation unit is disposed below the filter corresponding to each of the pressure compensation units.

15. The apparatus of claim 14, wherein a height difference between each of the pressure compensation units and the filter corresponding to each of the pressure compensation units is the same.

16. The apparatus of claim 13, wherein the drainage line includes:
a first drainage line connected to the pressure compensation unit upstream of the pressure compensation unit; and
a second drainage line connected to the pressure compensation unit downstream of the pressure compensation unit,
the pressure compensation unit is a reverse flow line, and
the reverse flow line connects the first drainage line and the second drainage line, and is provided to rise when the treatment liquid flows from the first drainage line to the second drainage line.

17. The apparatus of claim 13, wherein the drainage line includes:
a first drainage line connected to the pressure compensation unit upstream of the pressure compensation unit; and
a second drainage line connected to the pressure compensation unit downstream of the pressure compensation unit,
the pressure compensation unit includes:
a body having a space therein;
an open line connected to the body; and
a valve installed in the open line, and
the first drainage line and the second drainage line are coupled to the body.

18. An apparatus for processing a substrate, the apparatus comprising:
a plurality of treating chambers which processes a substrate with a treatment liquid and is arranged in a vertical direction; and
a treatment liquid supply unit for supplying a treatment liquid to the plurality of treating chambers,
wherein the treatment liquid supply unit includes:
a treatment liquid supply source for storing and supplying the treatment liquid;
an upstream supply line connected to the treatment liquid supply source;
a plurality of downstream supply lines branching from the upstream supply line to be connected to the plurality of treating chambers, respectively;
a pump unit installed on each of the downstream supply lines to feed the treatment liquid from the treatment liquid supply source to the treating chamber;
a drainage line which is connected to the pump unit to discharge the treatment liquid, and includes a vertical line discharging the treatment liquid vertically downward; and
a plurality of pressure compensation units installed on the vertical line and compensating for a pressure in the drainage line, and
a drain box connected to the plurality of drainage lines to discharge the treatment liquid drained from the drainage line to the outside,
the treatment liquid is photoresist,
the pump unit includes:
a pump for pressurizing and feeding the treatment liquid; and
a filter for filtering the treatment liquid, and
the pump unit is provided at a height corresponding to each of the plurality of treating chambers, and
each of the pressure compensation units is provided to have the same height difference as the corresponding pump unit, each of the pressure compensation units being disposed below the corresponding pump unit and being disposed above the pump unit disposed below the corresponding pump unit.

19. The apparatus of claim 18, wherein the drainage line includes:
a first drainage line connected to the pressure compensation unit upstream of the pressure compensation unit; and
a second drainage line connected to the pressure compensation unit downstream of the pressure compensation unit,
the pressure compensation unit is a reverse flow line, and
the reverse flow line connects the first drainage line and the second drainage line, and is provided to rise when the treatment liquid flows from the first drainage line to the second drainage line.

20. The apparatus of claim 18, wherein the drainage line includes:
a first drainage line connected to the pressure compensation unit upstream of the pressure compensation unit; and
a second drainage line connected to the pressure compensation unit downstream of the pressure compensation unit,
the pressure compensation unit includes:
a body having a space therein;
an open line connected to the body; and
a valve installed in the open line, and
the first drainage line and the second drainage line are coupled to the body.
